(19) United States
(12) Patent Application Publication
(10) Pub. No.: US 2024/0279544 A1
(43) Pub. Date: Aug. 22, 2024

(54) Wet-Resistant Fluoride Red Phosphor and Preparation and Application thereof, and White Light LED Device

(71) Applicant: HEFEI UNIVERSITY OF TECHNOLOGY, Hefei (CN)

(72) Inventors: Lei CHEN, Hefei (CN); Yanguang GUO, Hefei (CN); Shuanghong WEI, Hefei (CN); Qi LIU, Hefei (CN); Yabing WU, Hefei (CN); Ping CHEN, Hefei (CN); Guoqing TONG, Hefei (CN); Yang JIANG, Hefei (CN); Haiyong NI, Hefei (CN)

(21) Appl. No.: 18/582,689

(22) Filed: Feb. 21, 2024

(30) Foreign Application Priority Data
Feb. 21, 2023 (CN) 202310161936.1

(51) Int. Cl. C09K 11/67; C09K 11/59; C09K 11/62; G02F 1/13357; H01L 33/32; H01L 33/50

(52) U.S. Cl. CPC C09K 11/675; C09K 11/59; C09K 11/62; H01L 33/504; G02F 1/133603; H01L 33/32

(57) ABSTRACT

The present disclosure relates to the field of inorganic non-metallic optoelectronic functional materials, and discloses wet-resistant fluoride red phosphor and preparation and application thereof, and a white light LED device. The fluoride red phosphor is a core-shell structure: the core is Mn⁴⁺ doped fluoride red phosphor, and the chemical structural formula is A₂B₁₋ₓF₆:xMn⁴⁺, herein A is at least one of Li, Na, K, Rb, and Cs, B is at least one of Ti, Si, Ge, Zr, and Sn, and 0≤x≤0.4; and the shell is a cubic perovskite-type compound, and the chemical structural formula is CMgF₃, herein C is at least one of Li, Na, K, Rb, and Cs. The present disclosure uses CMgF₃ generated as a coating waterproof layer, to form the A₂B₁₋ₓF₆:xMn⁴⁺ core-shell structure of which the surface is coated by CMgF₃, and a wet-resistant problem of the fluoride red phosphor is overcome.

### TECHNICAL FIELD

The present disclosure relates to the field of inorganic non-metallic optoelectronic functional materials, in particular to wet-resistant fluoride red phosphor and preparation and application thereof, and a white light light-emitting diode (LED) device serving as a display backlight source.

### BACKGROUND OF THE INVENTION

At present, liquid crystal displays mainly use white light LEDs as backlight source. This type of the white light LEDs is fabricated by mainly packaging blue light LED chips in combination with red and green phosphors. For white light LED devices applied to display backlight sources, the emission spectra of the phosphor is narrower, and it is more beneficial to improve the color gamut range and color contrast of display, so that images displayed are more vivid and bright.

In order to meet the needs of liquid crystal displays and high-end lighting applications, a large number of scholars develop Mn⁴⁺ activated fluoride red phosphor in recent years. The Mn⁴⁺ activated fluoride red phosphor may be effectively excited by the blue light emitted by the LED chips, and it has the advantages such as narrowband red emission, high quantum efficiency, good thermal stability, and simple synthesis method. The d-d orbital electron forbidden transition of Mn⁴⁺ may emit a narrow band spectra, which may well meet the needs of display applications. The fluoride compounds have low phonon energy and thus have high efficiency in energy conversion. At present, the reported Mn⁴⁺ activated fluoride red phosphors mainly include fluorosilicate (K₂, Na₂, KNa, Ba, and Zn) SiF₆:Mn⁴⁺, fluorogermanate (Na₂, K₂, and Ba) GeF₆:Mn⁴⁺, fluorostannate (K₂, Na₂, and Cs₂) SnF₆·H₂O:Mn⁴⁺, and fluorotitanate (K₂, Na₂, Cs, and Ba) TiF₆:Mn⁴⁺ and other systems. Herein two materials, K₂SiF₆:Mn⁴⁺ and K₂GeF₆:Mn⁴⁺, are commercially applied already. However, all Mn⁴⁺ activated fluoride red phosphor has a key technical challenge of poor wet resistance. Once the Mn⁴⁺ activated fluoride red phosphors contacted with water and oxygen in the environment, a layer of black MnO₂ is formed on the surface of the phosphors, resulting in the luminescence efficiency of the phosphors is greatly reduced. In order to overcome this technical challenge, there is an urgent need to develop a technical means to improve the wet resistance of the fluoride red phosphor, or to develop high-efficiency fluoride red phosphor with wet resistance.

In order to make the fluoride phosphors achieve the well waterproof effect, a common way that has been adopted was by coating one or more layers of inorganic and organic substances on the surface of phosphor particles. By taking this measure, researchers make many attempts to improve the waterproof performance of the fluoride phosphor, and there are currently two mainstream surface modification methods.

One method is to construct a core-shell structure, and the surface of the phosphor is coated with a layer of an inorganic substance or an organic substance so as to achieve a purpose of isolating water molecules in the environment. For example:
a document (Zhou Y. Y., et. al., ACSAppl.Mater.Interfaces2018, 10, 880-889) reports that a layer of octadecyltrimethoxysilane (ODTMS) is attached to the surface of K₂TiF₆:Mn⁴⁺ (KTF) phosphor, it is dispersed in water for 2 h, and 84.3% of the initial luminescence intensity is retained;
a document (Li Y. L., et. al., J. Lumin., 2021, 234, 117968) reports that the surface of K₂SiF₆:Mn⁴⁺ (KSF) is coated with a layer of a K₂SiF₆ raw material without Mn⁴⁺, to form a KSF@K₂SiF₆ core-shell structure, it is soaked in water for 300 min, and the luminescence intensity maintains 88% of the initial intensity;
a document (Fang M. H., et. al., ACS Appl. Mater. Interfaces, 2018, 10, 29233-29237) reports that an oleic acid (OA) is used as a bridge, to form a KTF@OA@SiO₂ double-layer core-shell structure on the surface of KTF, and it has the better water resistance;
a document (Fang Z. Y., et. al., Int. J. Appl. Ceram. Technol, 2021, 18, 1106-1113) reports that the surface of KTF is coated with SrF₂ as a waterproof layer, and a document (Yu Y, et. al., Ceram. Int., 2021, 47, 33172-33179) reports that the surface of KTF is coated with CaF₂ as a waterproof layer; and
a document (Dong Q. Z., et. al., Mater. Res. Bull., 2019, 115, 98-104) reports that the surface of KTF is coated with CaF₂ as a waterproof layer, which significantly improves the wet resistance of the phosphor.

Another method is surface modification, means such as acid reduction or ion exchange is used, to reduce the concentration of Mn⁴⁺ on the surface of phosphor particles and prevent the occurrence of the browning effect. For example:
a document (Wan P. P., et. al., Chem. Eng. J., 2021, 426, 131350.) and a document (Luo P. L., et, al., Chem. Eng. J., 2022, 435, 134951) report that methods of surface passivation and ion exchange are used, a strategy of reduction assisted surface recrystallization is used for surface reconstruction, and after boiling in water, the quantum efficiency (QE) is 96.68%;
a document (Zhou Y. Y., et. al., ACS Appl. Mater. Interfaces, 2019, 6, 1802006) reports that H₂O₂ is used for surface passivation; and
a document (Liu Y., et. al., Ceram. Int., 2022, 46, 18281-18286) reports that H₂O₂ is also used to passivate the surface of the fluoride phosphor, which greatly improves the wet resistance of the phosphor.

Although these technologies may improve the waterproof performance to a certain extent, it still may not completely overcome the wet resistance problem of the fluoride red phosphor, and it is urgent to find a new water-resistant surface substance and develop a new surface coating technology.

### SUMMARY OF THE INVENTION

A purpose of the present disclosure is to provide wet-resistant fluoride red phosphor and preparation and application thereof, and a white light LED device serving as a display backlight source in response to the deficiencies of existing technologies. The present disclosure uses CMgF₃ generated as a coating waterproof layer, to form an A₂B₁₋ₓF₆:xMn⁴⁺ core-shell structure of which the surface is coated by CMgF₃, and a wet-resistant problem of the fluoride red phosphor is overcome.

In order to achieve the above purpose, a first aspect of the present disclosure provides wet-resistant fluoride red phosphor, and the fluoride red phosphor is a core-shell structure:
the core is Mn⁴⁺ doped fluoride red phosphor, and the chemical structural formula is A₂B₁₋ₓF₆:xMn⁴⁺, herein A is at least one of Li, Na, K, Rb, and Cs, B is at least one of Ti, Si, Ge, Zr, and Sn, and 0≤x≤0.4; and
the shell is a cubic perovskite-type compound, and the chemical structural formula is CMgF₃, herein C is at least one of Li, Na, K, Rb, and Cs.

According to the present disclosure, preferably the molar ratio of the shell to the core is 0.005-1.0.

According to the present disclosure, preferably A is at least one of Na and K, B is at least one of Ti and Si, and C is at least one of Na and K.

According to the present disclosure, preferably the molar ratio of the shell to the core is 0.2, 0.4, 0.6, 0.8, or 1.0, which is set as x all over the document.

According to the present disclosure, preferably the fluoride red phosphor is K₂TiF₆: 0.08Mn⁴⁺@KMgF₃, the molar ratio of the shell to the core is 0.2.

According to the present disclosure, preferably the fluoride red phosphor is K₂SiF₆: 0.08Mn⁴⁺@ KMgF₃, the molar ratio of the shell to the core is 0.2.

According to the present disclosure, preferably the fluoride red phosphor is K₂TiF₆: 0.08Mn⁴⁺@NaMgF₃, the molar ratio of the shell to the core is 0.2.

In the present disclosure, “@” means the surface of substance before it is coated with the substance behind it. For example, “K₂TiF₆: 0.08Mn⁴⁺@KMgF₃” means that the surface of K₂TiF₆: 0.08Mn⁴⁺ is coated with KMgF₃.

In the present disclosure, as a preferred scheme, the Mn⁴⁺ doped fluoride red phosphor is prepared by a means of secondary crystallization assisted with ion exchange.

A second aspect of the present disclosure provides a preparation method for the wet-resistant fluoride red phosphor, including the following steps:
S1: CHF₂ aqueous solution and Mg(NO₃)₂ aqueous solution are prepared, herein C is at least one of Li, Na, K, Rb, and Cs;
S2: the Mn⁴⁺ doped fluoride red phosphor is mixed with the CHF₂ aqueous solution and it is stirred uniformly, to obtain mixed solution;
S3: the mixed solution is continuously stirred, the Mg(NO₃)₂ aqueous solution is dropwise added into the mixed solution, and after dropwise adding, stirring, solid-liquid separating, washing, and drying are performed sequentially, to obtain A₂B₁₋ₓF₆:xMn⁴⁺ core-shell structure fluoride red phosphor of which the surface is coated with CMgF₃; and
S4: the A₂B₁₋ₓF₆:xMn⁴⁺ core-shell structure fluoride red phosphor of which the surface is coated with CMgF₃ is soaked in water, and the solid-liquid separating, washing, and drying are performed, to obtain the wet-resistant fluoride red phosphor.

According to the present disclosure, preferably the molar concentration of the CHF₂ aqueous solution is 0.001-10 mol/L.

According to the present disclosure, preferably the molar concentration of the Mg(NO₃)₂ aqueous solution is 0.001-10 mol/L.

According to the present disclosure, preferably the usage amount ratio of the CHF₂ aqueous solution, the Mg(NO₃)₂ aqueous solution, and the Mn⁴⁺ doped fluoride red phosphor is (0.01-30) L: (0.01-10) L: 1 g.

According to the present disclosure, preferably the molar amount of the Mn⁴⁺ doped fluoride red phosphor is 0.001-0.40 mol.

According to the present disclosure, preferably in Step S2, the stirring rate is 50-1200 rpm, and the stirring time is 0-60 min.

According to the present disclosure, preferably in Step S3,
the stirring rate of the continuously stirring is 50-1200 rpm;
the stirring rate after the dropwise adding is 50-1200 rpm, and the stirring time is 0-60 min; and
the dripping rate is 1-90 seconds/drop.

In the present disclosure, the mode of the solid-liquid separating includes suction filtration, and the washing includes repeatedly washing a filter cake with ethanol to neutral.

According to the present disclosure, preferably in Step S4, the soaking time is 1-60 h.

According to the present disclosure, preferably in Step S4, the soaking time is 12 h, 24 h, 48 h, or 60 h.

According to the present disclosure, preferably the preparation method including the following steps:
S1: preparing KHF₂ aqueous solution and the Mg(NO₃)₂ aqueous solution;
S2: mixing K₂TiF₆:xMn⁴⁺ with the KHF₂ aqueous solution and stirring for 30 min, to obtain mixed solution;
S3: continuously stirring the mixed solution, dropwise adding the Mg(NO₃)₂ aqueous solution into the mixed solution, and after dropwise adding, performing stirring for 30 min, performing solid-liquid separating, washing, and performing drying at 70° C., to obtain K₂TiF₆:xMn⁴⁺@KMgF₃; and
S4: soaking the K₂TiF₆:Mn⁴⁺@KMgF₃ in water for 24 h, and performing the solid-liquid separating, washing, and drying, to obtain the wet-resistant fluoride red phosphor.

In the present disclosure, as a preferred scheme, the coating process of the present disclosure is that in potassium hydrogen fluoride solution, Mg²⁺, K⁺, and F⁻ ions form a KMgF₃ precipitate on the surface of K₂TiF₆:Mn⁴⁺ phosphor particles, and the entire phosphor particles are coated, to form a waterproof layer and block the contact between [MnF₆]²⁺ groups on the surface of the phosphor and the water in the environment, thereby the wet resistance of the phosphor is greatly improved. After the coating is completed, K₂TiF₆:Mn⁴⁺@KMgF₃ phosphor obtained is soaked in water for 24 h. The KMgF₃ shell layer on the surface of the phosphor, which is difficult to dissolve in water, undergoes recrystallization in water, to form K₂TiF₆:Mn⁴⁺@KMgF₃ phosphor with regular surface morphology and water resistance. As shown in FIG. 1:
(1) K₂TiF₆:Mn⁴⁺ phosphor is mixed with the potassium hydrogen fluoride solution and it is stirred for 30 min, to obtain mixed solution;
(2) the mixed solution is continuously stirred, the Mg(NO₃)₂ aqueous solution is dropwise added into the mixed solution at a constant dripping rate, at this time, KMgF₃ slowly grows on the surface of K₂TiF₆:Mn⁴⁺ phosphor particles, and after dropwise adding, stirring for 30 min, solid-liquid separating, washing, and drying (70° C.) are performed sequentially, to obtain K₂TiF₆:Mn⁴⁺@KMgF₃ phosphor of which the surface morphology presents an irregular sphere, as shown in FIG. 1(2); and
(3) the K₂TiF₆:Mn⁴⁺@KMgF₃ phosphor is soaked in water for 24 h, KMgF₃ on the surface of the phosphor is recrystallized in water, and the surface morphology becomes relatively regular and smooth, as shown in FIG. 1(3), and the solid-liquid separating, washing, and drying are performed, to obtain the wet-resistant fluoride red phosphor.

A third aspect of the present disclosure provides an application of the wet-resistant fluoride red phosphor used as a red component of a white light LED device serving as a display backlight source.

A fourth aspect of the present disclosure provides a white light LED device serving as a display backlight source, and the white light LED device includes a red component, a green component, and a blue component; and
the red component is the wet-resistant fluoride red phosphor.

According to the present disclosure, preferably the green component is a green phosphor with a peak emission wavelength of 520-560 nm and a half peak width of less than 35 nm, preferably β-SIALON green phosphor; and the blue component is an InGaN blue-emitting chip.

The beneficial effects of the technical schemes of the present disclosure are as follows.

The present disclosure uses a simple co-precipitation method to complete the coating of CMgF₃ layer on fluoride phosphor particles in CHF₂ aqueous solution, the usage amount of the hydrofluoric acid is reduced, the synthesis hazard is reduced, and the generated CMgF₃ is used as the coating waterproof layer, to form the A₂B₁₋ₓF₆:xMn⁴⁺ core-shell structure of which the surface is coated by CMgF₃. The coating process is simple, it is environment-friendly, resources are saved, and it is suitable for large-scale industrial applications.

The absorbance, internal quantum efficiency, and external quantum efficiency of the Mn⁴⁺ doped fluoride red phosphor which is not soaked in water, are 71.22%, 83.48%, and 59.47%, and after being soaked in water for 24 h, it still maintains 98.15%, 96.55%, and 94.8% of the initial values. The wet-resistant fluoride red phosphor prepared by the present disclosure still has the good luminescent performance even when soaked in pure water. The absorbance, internal quantum efficiency, and external quantum efficiency of the A₂B₁₋ₓF₆:xMn⁴⁺ core-shell structure fluoride red phosphor, of which the surface is coated by CMgF₃, after being soaked in water for 24 h are 72.56%, 86.46%, and 62.73%, respectively.

The present disclosure uses the A₂B₁₋ₓF₆:xMn⁴⁺ fluoride red phosphor as the core and uses CMgF₃ as the surface coating layer substance, the coated phosphor is soaked in the aqueous solution for a long time and then filtered out for use. This process is used to thoroughly overcome the problem that the Mn⁴⁺ activated fluoride red phosphor is afraid of wet.

Other features and advantages of the present disclosure are partially described in detail in subsequent specific implementation modes.

### BRIEF DESCRIPTION OF DRAWINGS

By describing exemplary implementation modes of the present disclosure in more detail in combination with drawings, the above and other purposes, features, and advantages of the present disclosure may become more apparent, herein in the exemplary implementation modes of the present disclosure, the same reference signs typically represent the same components.

FIG. 1 shows a schematic diagram of a preparation process (coating process and recrystallization process) of K₂TiF₆:Mn⁴⁺@KMgF₃ phosphor provided in Example 1 of the present disclosure (herein, “KTF @KMgF₃” is K₂TiF₆:Mn⁴⁺@KMgF₃).

FIG. 2 shows a photo of K₂TiF₆:Mn⁴⁺ core-shell structure fluoride red phosphor, of which the surface is coated by KMgF₃, soaked in water for 24 h in Example 1 of the present disclosure.

FIG. 3 shows X-ray diffraction (XRD) patterns of K₂TiF₆:Mn⁴⁺@KMgF₃ phosphor with different coating ratios in Examples 1-5 of the present disclosure. (Herein, “2 Theta (°)” represents an XRD scanning angle, similarly hereinafter.)

FIG. 4 shows emission spectra of the K₂TiF₆:Mn⁴⁺@KMgF₃ phosphor with the different coating ratios after being soaked in water for 24 h in Examples 1-5 of the present disclosure.

FIG. 5 shows excitation spectra of the K₂TiF₆:Mn⁴⁺@KMgF₃ phosphor with the different coating ratios after being soaked in water for 24 h in Examples 1-5 of the present disclosure.

FIG. 6 shows XRD Patterns of the K₂TiF₆:Mn⁴⁺@KMgF₃ phosphor with different soaking times in Example 1, and 6-9 of the present disclosure.

FIGS. 7 (a), (c), (e), and (g) respectively shows a scanning electron microscope (SEM) image of K₂TiF₆:Mn⁴⁺ uncoated in Example 1, an SEM image of K₂TiF₆:Mn⁴⁺@KMgF₃ in Example 1, an SEM image of K₂TiF₆:Mn⁴⁺@KMgF₃ soaked in water for 24 h in Example 1, and an SEM image of K₂TiF₆:Mn⁴⁺@KMgF₃ soaked in water for 60 h in Example 1.

FIGS. 7 (b), (d), (f), and (h) respectively shows an energy dispersive spectrometer (EDS) elemental mapping of K₂TiF₆:Mn⁴⁺ uncoated in Example 1, an EDS elemental mapping of K₂TiF₆:Mn⁴⁺@KMgF₃ in Example 1, an EDS elemental mapping of K₂TiF₆:Mn⁴⁺@KMgF₃ soaked in water for 24 h in Example 1, and an EDS elemental mapping of K₂TiF₆:Mn⁴⁺@KMgF₃ soaked in water for 60 h in Example 1. Herein, Mn Kα1 represents a characteristic X-ray signal released by excited electrons in an L layer outside an Mn element atomic nucleus transitioning to a K layer, resulting in energy loss, and represents a signal of the Mn element detected by an energy spectrometer; and Mg Kα1_2 represents a characteristic X-ray signal released by excited electrons in an L layer outside an Mg element atomic nucleus transitioning to a K layer, resulting in energy loss, and represents a signal of the Mg element detected by the energy spectrometer.

FIG. 8 shows emission spectra of K₂TiF₆:Mn⁴⁺@KMgF₃ phosphor with different soaking times in Examples 1, and 6-9.

FIG. 9 shows excitation spectra of the K₂TiF₆:Mn⁴⁺@KMgF₃ phosphor with the different soaking times in Examples 1, and 6-9.

FIG. 10 shows emission spectra of samples in Examples 10-17 for a first orthogonal experiment.

FIG. 11 shows emission spectra of samples in Examples 18-25 for the first orthogonal experiment.

FIG. 12 shows emission spectra of samples in Examples 10-17 for a second orthogonal experiment.

FIG. 13 shows emission spectra of samples in Examples 18-25 for the second orthogonal experiment.

FIG. 14 shows XRD Patterns of K₂SiF₆:Mn⁴⁺@KMgF₃ phosphor with different coating ratios in Examples 26-30. (“KSF @KMgF₃” is K₂SiF₆:Mn⁴⁺@KMgF₃.)

FIG. 15 (a)-(f) shows an SEM image of K₂SiF₆:Mn⁴⁺ uncoated in Example 26 ((a)-(b)), an SEM image of K₂SiF₆:Mn⁴⁺@ KMgF₃ in Example 26 ((c)-(d)), and an SEM image of K₂SiF₆:Mn⁴⁺@ KMgF₃ soaked in water for 24 h in Example 26 ((e)-(f)).

FIG. 16 shows emission spectra of K₂SiF₆:Mn⁴⁺@KMgF₃ phosphor with different coating ratios after being soaked in water for 24 h in Examples 26-30.

FIG. 17 shows excitation spectra of the K₂SiF₆:Mn⁴⁺@KMgF₃ phosphor with the different coating ratios after being soaked in water for 24 h in Examples 26-30.

FIG. 18 shows XRD Patterns of K₂TiF₆:Mn⁴⁺@NaMgF₃ phosphor with different coating ratios in Examples 31-35.

FIG. 19 shows emission spectra of the K₂TiF₆:Mn⁴⁺@NaMgF₃ phosphor with the different coating ratios after being soaked in water for 24 h in Examples 31-35.

FIG. 20 shows excitation spectra of the K₂TiF₆:Mn⁴⁺@NaMgF₃ phosphor with the different coating ratios after being soaked in water for 24 h in Examples 31-35.

FIG. 21 (a) shows a spectra of a white light LED device packaged with K₂TiF₆:Mn⁴⁺@KMgF₃ in Example 1.

FIG. 21 (b) shows a comparison diagram of a CIE color gamut diagram of the white light LED device in Example 36 and a standard color gamut of the National Television System Committee (the United States). (Herein, NTSC is the standard color gamut of the National Television System Committee.

FIG. 22 shows a thermal steady-state luminous flux attenuation curve of the white light LED device packaged with K₂TiF₆:Mn⁴⁺ (1), K₂TiF₆:Mn⁴⁺@KMgF₃ but not soaked in water (2), and K₂TiF₆:Mn⁴⁺@KMgF₃ after being soaked in water for 24 h (3).

FIG. 23 shows a thermal steady-state voltage attenuation curve of the white light LED device packaged with K₂TiF₆:Mn⁴⁺ (1), K₂TiF₆:Mn⁴⁺@KMgF₃ but not soaked in water (2), and K₂TiF₆:Mn⁴⁺@KMgF₃ after being soaked in water for 24 h (3).

FIG. 24 shows XRD Patterns of K₂TiF₆:Mn⁴⁺ core-shell structure fluoride red phosphor of which the surface is coated by KMgF₃ in Example 1.

FIG. 25 shows XRD Patterns of K₂TiF₆:Mn⁴⁺@CaF₂ and K₂TiF₆:Mn⁴.

FIG. 26 shows XRD Patterns of K₂TiF₆:Mn⁴⁺@SrF₂ and K₂TiF₆:Mn⁴.

### DETAILED DESCRIPTION OF THE INVENTION

Preferred embodiments of the present disclosure are described in more detail below. Although the preferred embodiments of the present disclosure are described below, it should be understood that the present disclosure may be implemented in various forms and should not be limited by the embodiments described herein. On the contrary, these embodiments are provided to make the present disclosure more thorough and complete, and fully convey the scope of the present disclosure to those skilled in the art.

In the following examples:
Mn⁴⁺ doped fluoride red phosphor was prepared by a means of secondary crystallization assisted with ion exchange;
KHF₂ was purchased from Shanghai SanAiSi Reagent Co., Ltd., and the analytical purity AR is 99%;
Mg(NO₃)₂·6H₂O was purchased from Tianjin Damao Chemical Reagent Factory, and the analytical purity AR is 99%; and
anhydrous ethanol was purchased from Sinopharm Group Chemical reagent Co., Ltd, and the analytical purity is 99.7%.

### Example 1

This example provided wet-resistant fluoride red phosphor K₂TiF₆:Mn⁴⁺@KMgF₃, and the fluoride red phosphor was a core-shell structure;
the core was K₂TiF₆:Mn⁴⁺, herein the doping concentration of Mn⁴⁺ was x=0.08; and
the shell was KMgF₃.

The molar ratio of the shell to the core (coating ratio) was 0.2.

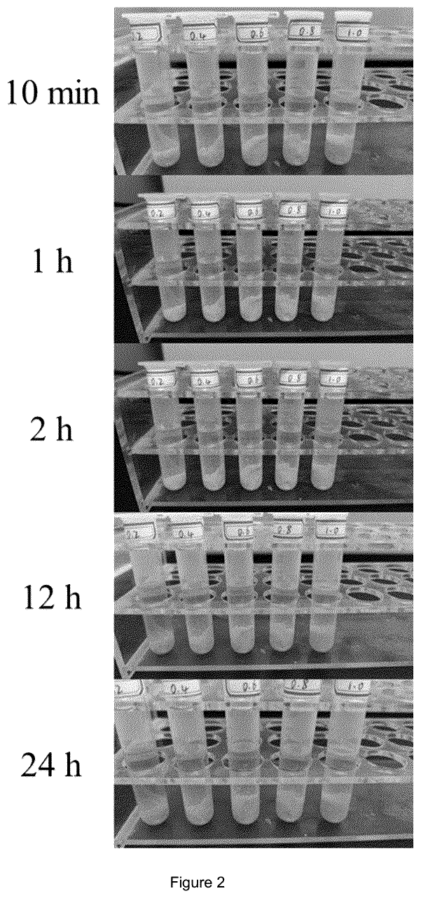

A preparation method for the above wet-resistant fluoride red phosphor included the following steps:
S1: 2 mol/L KHF₂ aqueous solution and 1 mol/L Mg(NO₃)₂ aqueous solution were prepared, herein C was at least one of Li, Na, K, Rb, and Cs;
S2: the above K₂TiF₆:Mn⁴⁺ (the molar amount was 0.01 mol) was mixed with 20 mL of the KHF₂ aqueous solution and it was stirred at 400 rpm for 30 min, to obtain mixed solution;
S3: the mixed solution was continuously stirred (400 rpm), the Mg(NO₃)₂ aqueous solution was dropwise added into the mixed solution (60 seconds/drop), and after dropwise adding, stirring (400 rpm) for 30 min, suction-filtering, washing with anhydrous ethanol to neutral, and drying (70° C.) were performed sequentially, to obtain K₂TiF₆:Mn⁴⁺ core-shell structure fluoride red phosphor of which the surface was coated with KMgF₃; and
S4: the K₂TiF₆:Mn⁴⁺ core-shell structure fluoride red phosphor of which the surface was coated with KMgF₃ was soaked in water for 24 h (as shown in FIG. 2), and the suction-filtering, washing, and drying (70° C.) were performed, to obtain the wet-resistant fluoride red phosphor.

### Examples 2-5

Wet-resistant fluoride red phosphor was respectively provided in Examples 2-5:

K₂TiF₆:Mn⁴⁺@KMgF₃.

The difference between Examples 2-5 and Example 1 was that the molar ratios (coating ratio) of shell KMgF₃ to core K₂TiF₆:Mn⁴⁺ in Examples 2-5 were 0.4, 0.6, 0.8, and 1.0 respectively.

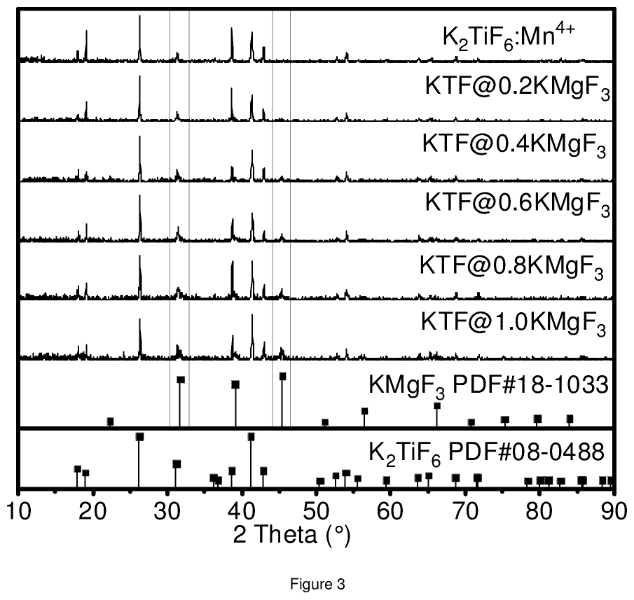

As shown in FIG. 3, XRD Patterns of K₂TiF₆:Mn⁴⁺@KMgF₃ phosphor with the different coating ratios in Examples 1-5 were presented, and it might be seen that:
the uncoated K₂TiF₆:Mn⁴⁺ corresponded well with the standard PDF #08-0488 of K₂TiF₆.

After being coated, as shown in a rectangular box in the figure, the characteristic peak of KMgF₃ appeared at diffraction angles of 31.63° and 45.42°, which was consistent with the main peak of the standard PDF #18-1033 of KMgF₃, corresponding to (110) and (200) crystal planes of KMgF₃ respectively. When the molar ratio of K₂TiF₆:Mn⁴⁺ to Mg²⁺ was increased from 0.2 to 1.0, the relative peak intensity of the characteristic peak was gradually increased, it was indicated that the coating thickness was increased. However, the main peak of K₂TiF₆:Mn ⁴⁺ was not shifted, it was indicated that the generation of KMgF₃ did not affect the basic structure of K₂TiF₆.

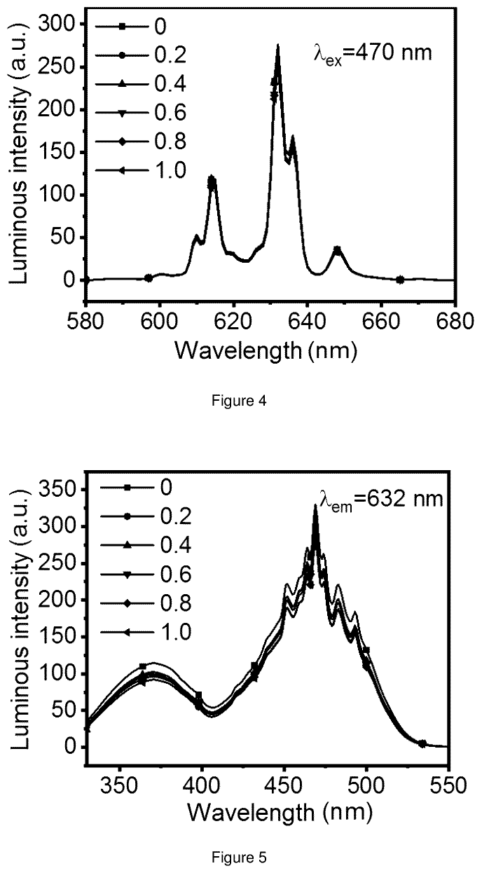

As shown in FIGS. 4 and 5, emission spectra and excitation spectra of K₂TiF₆:Mn⁴⁺@KMgF₃ phosphor with the different coating ratios after being soaked in water for 24 h in Examples 1-5 were presented, and it might be seen that: as the coating ratio was gradually increased, the luminescence intensity of K₂TiF₆:Mn⁴⁺@ xKMgF₃ phosphor was gradually decreased.

As shown in Table 1, it was the relative peak intensity and relative integral intensity of the emission spectra in FIG. 4. According to Table 1, when the coating ratio was 0.2, the relative peak intensity was closest to the uncoated K₂TiF₆:Mn⁴⁺, and reaches 99.24%. When the coating ratio was increased to 1.0, the peak intensity was 90.7% of the initial phosphor. Therefore, the surface modification was performed by adopting the scheme provided by the present disclosure, the wet resistance of the phosphor might reach up to 99.24%, almost without reducing the initial luminescent performance of the phosphor.

TABLE 1

| | Coating ratio | | | | | |
|---|---|---|---|---|---|---|
| | 0 | 0.2 | 0.4 | 0.6 | 0.8 | 1.0 |
| Peak intensity | 276.2 | 274.1 | 273.1 | 258.1 | 257.9 | 250.5 |
| Integral intensity | 3023.157 | 3033.092 | 3010.387 | 2862.833 | 2854.629 | 2784.897 |

### Examples 6-9

Wet-resistant fluoride red phosphor was respectively provided in Examples 6-9:

K₂TiF₆:Mn⁴⁺@KMgF₃.

The difference between Examples 6-9 and Example 1 was that: in Step S4, the K₂TiF₆:Mn ⁴⁺ core-shell structure fluoride red phosphor of which the surface was coated with KMgF₃ was soaked in water for 12 h, 36 h, 48 h, and 60 h respectively.

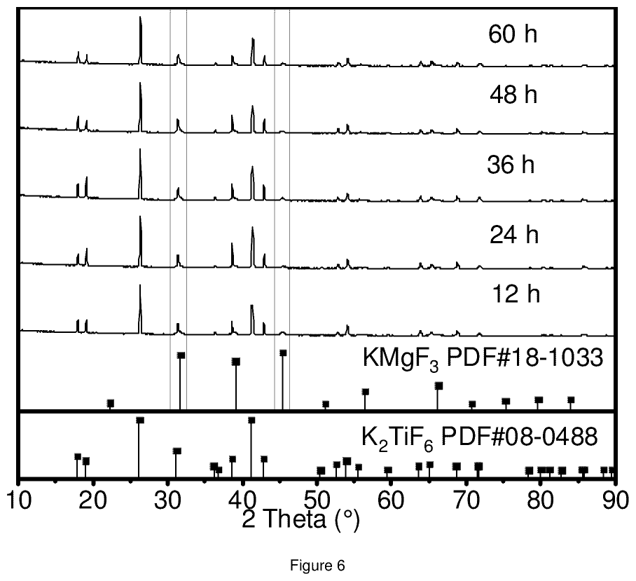

As shown in FIG. 6, XRD Patterns of K₂TiF₆:Mn⁴⁺@KMgF₃ phosphor with different soaking times in Examples 1 and 6-9 were presented, and it might be seen that: the relative peak intensity of the characteristic peak at the diffraction angles of 31.63° and 45.42° was not significantly decreased with the increase of the soaking time, it was indicated that the solubility of the KMgF₃ shell layer was very low and was prone to recrystallization.

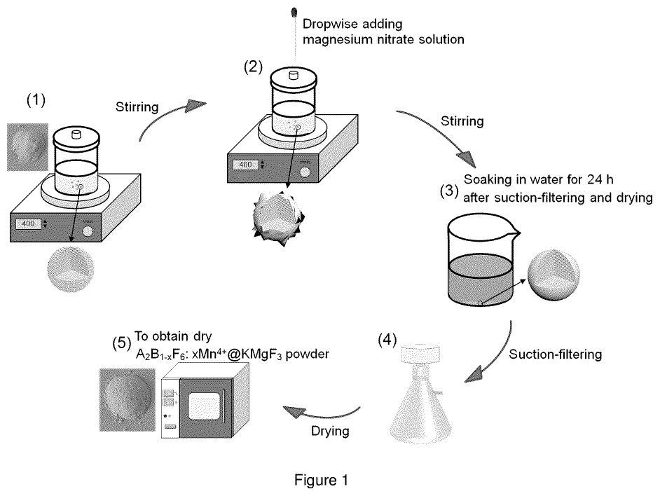

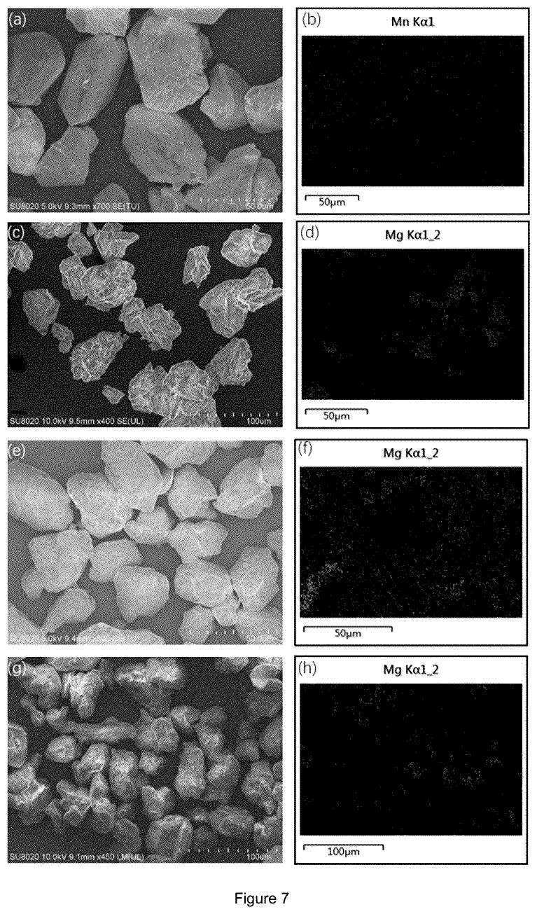

As shown in FIGS. 7 (a), (c), (e), and (g), an SEM image of uncoated K₂TiF₆:Mn⁴⁺ in Example 1, an SEM image of K₂TiF₆:Mn⁴⁺@KMgF₃ in Example 1, an SEM image of K₂TiF₆:Mn ⁴⁺@KMgF₃ soaked in water for 24 h in Example 1, and an SEM image of K₂TiF₆:Mn⁴⁺@KMgF₃ soaked in water for 60 h in Example 9 were presented respectively, and it might be seen that:
the surface morphology of the uncoated K₂TiF₆:Mn⁴⁺ was regular and flat;
the surface of the K₂TiF₆:Mn⁴⁺@KMgF₃ that was coated but not soaked in water was irregular; and
the surface of the K₂TiF₆:Mn⁴⁺@KMgF₃ particles soaked in water for 24 h and 60 h gradually became regular and flat, corresponding to the changes in the surface morphology of the phosphor particles in FIG. 1.

As shown in FIGS. 7 (b), (d), (f), and (h), an EDS elemental mapping of uncoated K₂TiF₆:Mn ⁴⁺ in Example 1, an EDS elemental mapping of K₂TiF₆:Mn⁴⁺@KMgF₃ in Example 1, an EDS elemental mapping of K₂TiF₆:Mn⁴⁺@KMgF₃ soaked in water for 24 h in Example 1, and an EDS elemental mapping of K₂TiF₆:Mn⁴⁺@KMgF₃ soaked in water for 60 h in Example 9 were presented respectively, and it might be seen that:
when it was not coated, there was no a signal of Mg on the surface of the particles; and
after being coated and soaked in water for a certain period of time, there was a signal of Mg presented. Corresponding to FIG. 1, KMgF₃ was grown on the surface of the phosphor particles.

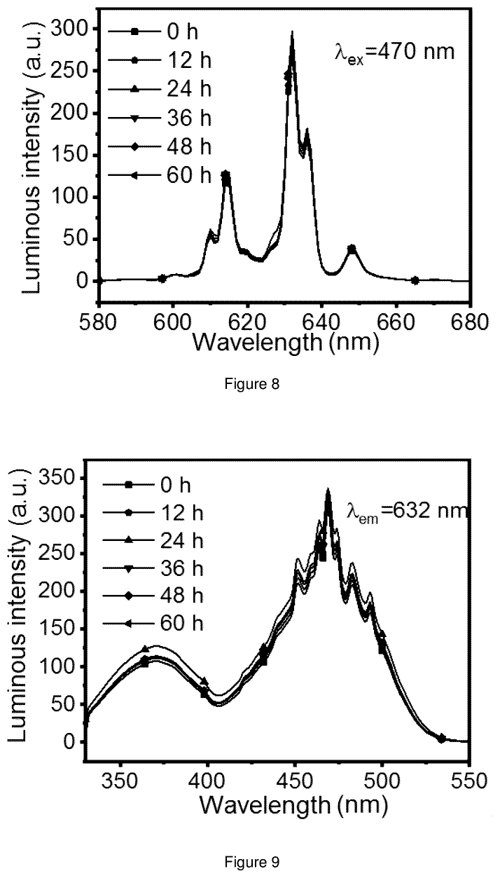

As shown in FIGS. 8 and 9, emission spectra and excitation spectra of K₂TiF₆:Mn⁴⁺@KMgF₃ phosphor with different soaking times in Examples 1 and 6-9 were presented, and it might be seen that: as the soaking time was increased, the relative peak intensity and relative integral intensity of the emission spectra were gradually increased, reach the maximum after 24 h of soaking, and then gradually became stabilized without increasing or decreasing. This phenomenon corresponded to the SEM image results of the coated phosphor soaked in water for the different times shown in FIGS. 7 (a), (c), (e), and (g). The surface morphology of K₂TiF₆:Mn⁴⁺@KMgF₃ phosphor that was coated but not soaked in water was irregular, which might affect the luminescent performance of the phosphor.

As shown in Table 2, it was the relative peak intensity and relative integral intensity of the emission spectra in FIG. 8. From Table 2, it might be seen that when the soaking time was 0, its luminescence intensity was the lowest, and after being soaked in water for a certain period of time, the luminescence intensity was gradually increased. This was because the KMgF₃ shell layer on the particle surface, which was difficult to dissolve in water, underwent recrystallization in water, and the surface tended to be regular and flat. Finally, the luminescence intensity of the phosphor was returned to the same level as K₂TiF₆:Mn⁴⁺ phosphor which was not coated but did not have the wet resistance.

TABLE 2

| | Time | | | | | |
|---|---|---|---|---|---|---|
| | 0 h | 12 h | 24 h | 36 h | 48 h | 60 h |
| Peak intensity | 270.7 | 281 | 295.5 | 297.2 | 296.4 | 295 |
| Integral intensity | 3009.354 | 3111.815 | 3343.793 | 3299.313 | 3297.482 | 3278.201 |

As shown in Table 3, the internal quantum efficiency, absorbance, and external quantum efficiency of K₂TiF₆:Mn⁴⁺ uncoated in Example 1, K₂TiF₆:Mn⁴⁺@KMgF₃ in Example 1, and K₂TiF₆:Mn⁴⁺@KMgF₃ soaked in water for 24 h in Example 1 were presented. Results showed that the external quantum efficiency of K₂TiF₆:Mn⁴⁺@KMgF₃ coated but not soaked in water was lower than that after being soaked for 24 h, and after being soaked for 24 h, the external quantum efficiency of K₂TiF₆:Mn⁴⁺@ KMgF₃ was returned to 94.8% of the initial uncoated K₂TiF₆:Mn⁴⁺.

TABLE 3

| | Internal | | External |
|---|---|---|---|
| | quantum | | quantum |
| Sample | efficiency | Absorbance | efficiency |
| K₂TiF₆:Mn⁴⁺ | 86.46% | 72.56% | 62.73% |
| K₂TiF₆:Mn⁴⁺ @KMgF₃ | 83.71% | 70.81% | 59.27% |
| K₂TiF₆:Mn⁴⁺ @KMgF₃- | 83.48% | 71.22% | 59.47% |
| Soaking for 24 h | | | |

### Examples 10-25

Wet-resistant fluoride red phosphor was respectively provided in Examples 10-25:

K₂TiF₆:Mn⁴⁺@KMgF₃.

The difference between Examples 10-25 and Example 1 was that:
the concentration of KHF₂ aqueous solution, the molar amount of K₂TiF₆:Mn⁴⁺ added, the concentration of Mg(NO₃)₂ aqueous solution, the dripping rate of the Mg(NO₃)₂ aqueous solution, and stirring rate were different, as shown in Table 5.

Examples 10-25 used Qualitek-4 orthogonal experimental analysis software to design a five-factor four-level orthogonal experiment, as shown in Table 4, the parameters of design range were presented.

TABLE 4

| Factor | Level 1 | Level 2 | Level 3 | Level 4 |
|---|---|---|---|---|
| KHF₂ solution concentration | 0.1 | 1 | 2 | 4 |
| (mol/L) | | | | |
| K₂TiF₆:Mn⁴⁺ molar amount (mol) | 0.001 | 0.005 | 0.01 | 0.02 |
| Mg(NO₃)₂ solution concentration | 0.1 | 1 | 2 | 4 |
| (mol/L) | | | | |
| Dripping rate (seconds/drop) | 1 | 30 | 60 | 90 |
| Stirring rate (rpm) | 50 | 400 | 800 | 1200 |

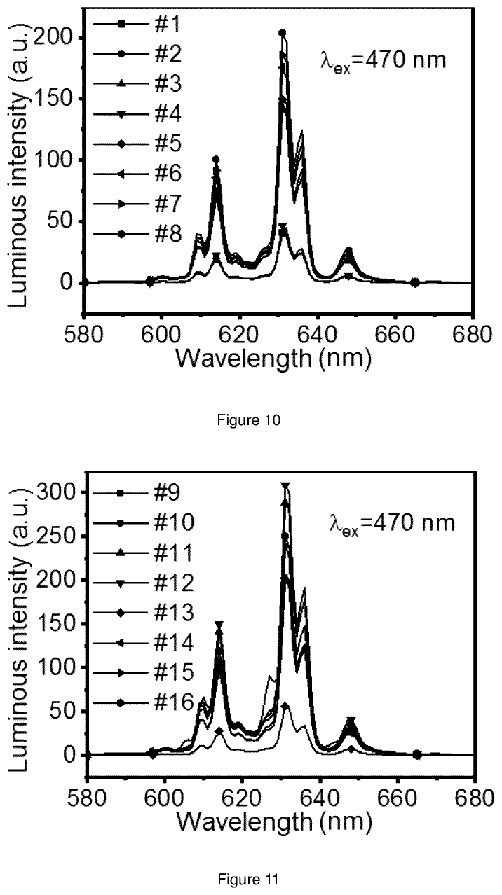

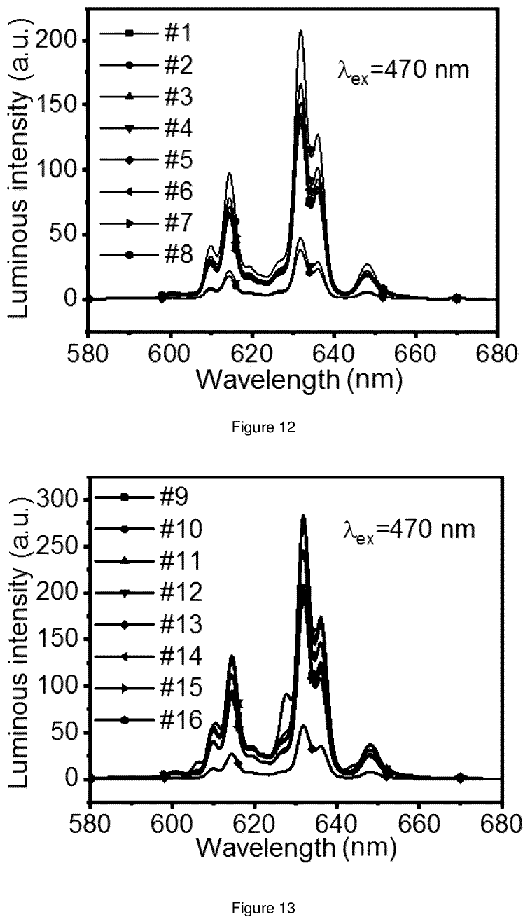

In order to ensure the accuracy of experimental results, two experiments were performed. FIGS. 10 and 11 showed emission spectra of samples 10-17 and 18-25 in the first orthogonal experiment respectively; FIGS. 12 and 13 showed emission spectra of samples 10-17 and 18-25 in the second orthogonal experiment respectively; and the average integral intensity of the results of two orthogonal experiments were shown in Table 5.

As shown in Table 6, statistical analysis results of the average integral intensity using the Qualitek-4 orthogonal experimental analysis software were specifically as follows:
the optimal solution concentration of KHF₂ was 2 mol/L corresponding to level 3;
the optimal molar amount of K₂TiF₆:Mn⁴⁺ phosphor added was 0.01 mol corresponding to level 3;
the optimal solution concentration of magnesium nitrate was 1 mol/L corresponding to level 2;
the optimal dripping rate was 60 s/drop corresponding to level 3; and
the optimal stirring rate was 50 r/min corresponding to level 1, and the influencing factor of the stirring rate was relatively low in proportion, and the contribution rate was 2.8% (49.868/1780.729). The uniformity of the solution system during the reaction was considered, so the stirring rate of 400 r/min was used for subsequent experiments.

TABLE 5

| | KHF₂ | KTF molar | Mg(NO₃)₂ | Dripping | Stirring | Average |
|---|---|---|---|---|---|---|
| | concentration | amount | concentration | rate | rate | integral |
| | (mol/L) | (mol) | (mol/L) | (s/drop) | (rpm) | intensity |
| Example 10 | 0.1 | 0.001 | 0.1 | 1 | 50 | 439.867 |
| Example 11 | 0.1 | 0.005 | 1 | 30 | 400 | 442.193 |
| Example 12 | 0.1 | 0.01 | 2 | 60 | 800 | 1540.502 |
| Example 13 | 0.1 | 0.02 | 4 | 90 | 1200 | 494.973 |
| Example 14 | 1 | 0.001 | 1 | 60 | 1200 | 1634.5645 |
| Example 15 | 1 | 0.005 | 0.1 | 90 | 800 | 1879.858 |
| Example 16 | 1 | 0.01 | 4 | 1 | 400 | 2010.5015 |
| Example 17 | 1 | 0.02 | 2 | 30 | 50 | 2204.42 |
| Example 18 | 2 | 0.001 | 2 | 90 | 400 | 2216.7205 |
| Example 19 | 2 | 0.005 | 4 | 60 | 50 | 2206.5955 |
| Example 20 | 2 | 0.01 | 0.1 | 30 | 1200 | 3137.917 |
| Example 21 | 2 | 0.02 | 1 | 1 | 800 | 3378.0465 |
| Example 22 | 4 | 0.001 | 4 | 30 | 800 | 600.322 |
| Example 23 | 4 | 0.005 | 2 | 1 | 1200 | 2210.838 |
| Example 24 | 4 | 0.01 | 1 | 90 | 50 | 2856.107 |
| Example 25 | 4 | 0.02 | 0.1 | 60 | 400 | 2776.64 |

TABLE 6

| | Level | | Contribution |
|---|---|---|---|
| Factor | description | Level | value |
| KHF₂ solution concentration (mol/L) | 2 | 3 | 857.941 |
| KTF molar amount (mol) | 0.01 | 3 | 509.377 |
| Mg(NO₃)₂ solution concentration | 1 | 2 | 200.848 |
| (mol/L) | | | |
| Dripping rate (seconds/drop) | 60 | 3 | 162.696 |
| Stirring rate (rpm) | 50 | 1 | 49.868 |

### Example 26

Wet-resistant fluoride red phosphor K₂SiF₆:Mn⁴⁺@KMgF₃ was provided in this example.

The fluoride red phosphor was a core-shell structure;
the core was K₂SiF₆:Mn⁴⁺, herein the doping concentration of Mn⁴⁺ was x=0.08; and
the shell was KMgF₃.

The molar ratio (coating ratio) of the shell to the core was 0.2.

A preparation method for the wet-resistant fluoride red phosphor in this example was the same as that in Example 1.

### Examples 27-30

Wet-resistant fluoride red phosphor was respectively provided in Examples 27-30:

K₂SiF₆:Mn⁴⁺@KMgF₃.

The difference between Examples 27-30 and Example 26 was that the molar ratios (coating ratio) of the shell KMgF₃ to core K₂SiF₆:Mn⁴⁺ in Examples 27-30 was 0.4, 0.6, 0.8, and 1.0 respectively.

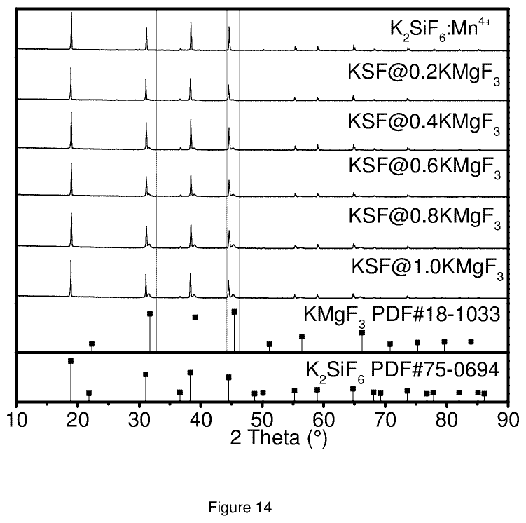

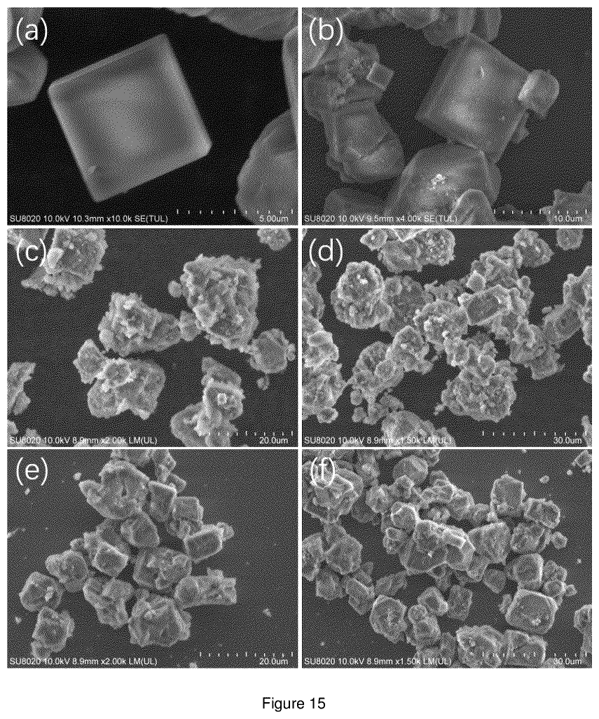

As shown in FIG. 14, XRD Patterns of K₂SiF₆:Mn⁴⁺@KMgF₃ phosphor with different coating ratios in Examples 26-30 were presented, and it might be seen that:
the uncoated K₂SiF₆:Mn⁴⁺ corresponded well with the standard PDF #75-0694 of K₂SiF₆.

After being coated, as shown in a rectangular box in the figure, the characteristic peak of KMgF₃ appeared at diffraction angles of 31.63° and 45.42°, which was consistent with the main peak of the standard PDF #18-1033 of KMgF₃, corresponding to (110) and (200) crystal planes of KMgF₃ respectively. When the molar ratio of K₂SiF₆:Mn⁴⁺ to Mg²⁺ was increased from 0.2 to 1.0, the relative peak intensity of the characteristic peak was gradually increased, it was indicated that the coating thickness was increased. However, the main peak of K₂SiF₆:Mn ⁴⁺ was not shifted, it was indicated that the generation of KMgF₃ did not affect the basic structure of K₂SiF₆.

As shown in FIG. 15 (a)-(f), an SEM image of K₂SiF₆:Mn⁴⁺ uncoated in Example 26 ((a)-(b)), an SEM image of K₂SiF₆:Mn⁴⁺@KMgF₃ in Example 26 ((c)-(d)), and an SEM image of K₂SiF₆:Mn⁴⁺@KMgF₃ soaked in water for 24 h in Example 26 ((e)-(f)) were presented respectively, and it might be seen that:
in FIG. 15 (a)-(b), the surface of the uncoated K₂SiF₆:Mn⁴⁺ was relatively smooth, and the phosphor particles were uniformly square in shape;
in FIG. 15 (c)-(d), the surface of K₂SiF₆:Mn⁴⁺@KMgF₃ was coated with an uneven shell layer, the particle surface was rough, but it might still be seen that the matrix of the phosphor particles was square; and
in FIG. 15 (e)-(f), the rough surface of K₂TiF₆:Mn⁴⁺@KMgF₃ soaked in water for 24 h in Example 26 became relatively smooth.

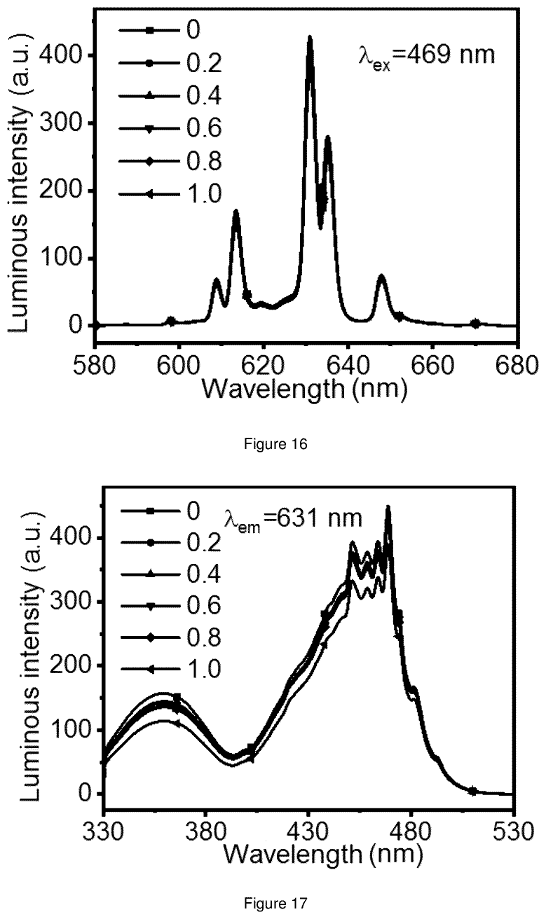

As shown in FIGS. 16 and 17, emission spectra and excitation spectra of K₂SiF₆:Mn⁴⁺@KMgF₃ phosphor with different coating ratios after being soaked in water for 24 h in Examples 26-30 were presented, and it might be seen that the decrease in luminescence intensity of the phosphor after being coated and soaked in water for 24 h was not significant compared to the untreated phosphor.

As shown in Table 7, they were the relative peak intensity and relative integral intensity of the emission spectra in FIG. 16. From Table 7, it might be seen that the results were consistent with the changes in luminescence intensity of K₂TiF₆:Mn⁴⁺ after being coated. As the coating ratio was increased, the luminescence intensity was gradually decreased. When x=0.2, wherein x was the molar ration of shell to core, the emission spectra integral intensity of K₂SiF₆:Mn⁴⁺@0.2KMgF₃ after being soaked in water for 24 h was 96.15% of the initial K₂SiF₆:Mn⁴⁺. When x=1.0, namely the coating ratio was largest and the shell layer was thickest, the emission spectra integral intensity of K₂SiF₆:Mn⁴⁺@1.0KMgF₃ after being soaked in water for 24 h was 87.38% of the initial K₂SiF₆:Mn⁴⁺.

TABLE 7

| | Coating ratio | | | | | |
|---|---|---|---|---|---|---|
| | 0 | 0.2 | 0.4 | 0.6 | 0.8 | 1.0 |
| Peak intensity | 427.4 | 411.5 | 404.5 | 388.1 | 387.3 | 376 |
| Integral intensity | 4045.89 | 3890.19 | 3832.42 | 3668.92 | 3669.51 | 3535.22 |

### Example 31

Wet-resistant fluoride red phosphor K₂TiF₆:Mn⁴⁺@NaMgF₃ was provided in this example.

The fluoride red phosphor was a core-shell structure;
the core was K₂TiF₆:Mn⁴⁺, which was the same as Example 1; and
the shell was NaMgF₃.

The molar ratio (coating ratio) of the shell to the core was 0.2.

The preparation method for the wet-resistant fluoride red phosphor in this example was the same as that in Example 1.

### Examples 32-35

Wet-resistant fluoride red phosphor was respectively provided in Examples 32-35:

K₂TiF₆:Mn⁴⁺@NaMgF₃.

The difference between Examples 32-35 and Example 31 was that the molar ratios (coating ratio) of the shell NaMgF₃ to the core K₂TiF₆:Mn⁴⁺ in Examples 32-35 were 0.4, 0.6, 0.8, and 1.0 respectively.

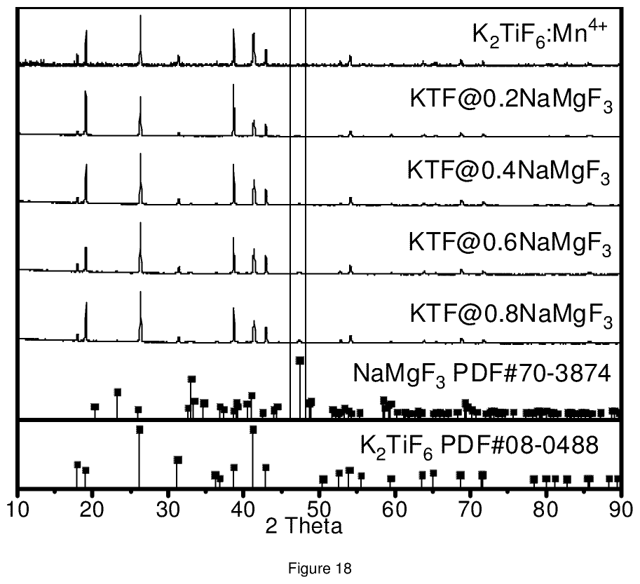

As shown in FIG. 18, XRD Patterns of K₂TiF₆:Mn⁴⁺@NaMgF₃ phosphor with different coating ratios in Examples 31-35 were presented, and it might be seen that:
the diffraction results of K₂TiF₆:Mn⁴⁺@NaMgF₃ corresponded accurately to the K₂TiF₆ standard PDF card, and the NaMgF₃ characteristic peak appeared at the diffraction angle of 47.3°, which corresponded accurately to the strongest peak on its standard PDF card. It was indicated that the coating method successfully synthesizes NaMgF₃ and forms a shell layer.

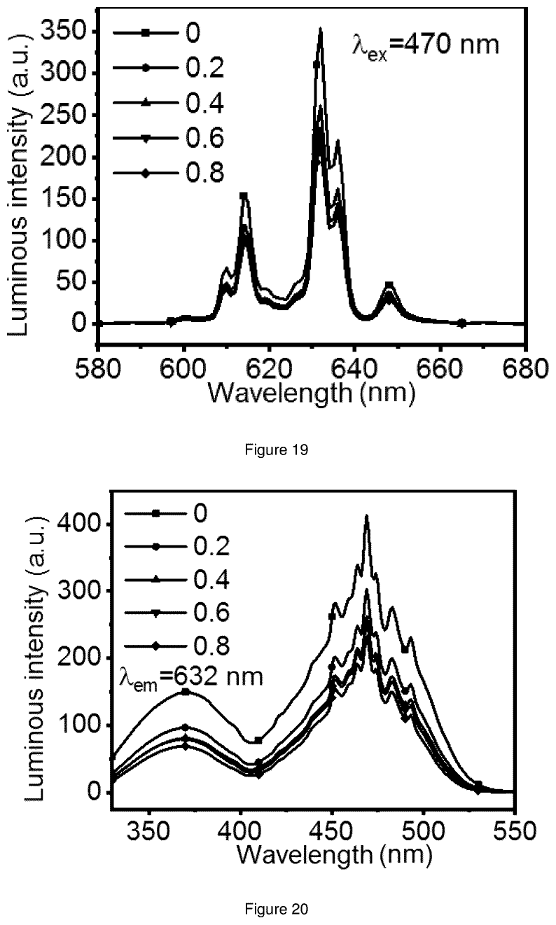

As shown in FIGS. 19 and 20, emission spectra and excitation spectra of K₂TiF₆:Mn⁴⁺@NaMgF₃ phosphor with the different coating ratios after being soaked in water for 24 h in Examples 31-35 were presented, and it might be seen that as the coating ratio was increased, the luminescence intensity was gradually decreased. When x=0.2, the integral intensity was 74.3% of the initial K₂TiF₆:Mn⁴⁺, and the waterproof performance was slightly lower than that of the KMgF₃ shell. When x=0.8, the peak intensity was 61.5% of the initial K₂TiF₆:Mn⁴⁺.

As shown in Table 8, it was the relative peak intensity and relative integral intensity of the emission spectra in FIG. 19.

TABLE 8

| Coating ratio | 0 | 0.2 | 0.4 | 0.6 | 0.8 |
|---|---|---|---|---|---|
| Peak intensity | 353.6 | 261.4 | 233.9 | 231.5 | 216.1 |
| Integral intensity | 3855.41 | 2864.35 | 2553.23 | 2537.74 | 2370.15 |

### Example 36

A white light LED device serving as a display backlight source was provided in this example, and the white light LED device included a red component, a green component, and a blue component;
the red component was the wet-resistant fluoride red phosphor in Example 1;
the green component was the β-SIALON:Eu²⁺ green phosphor; and
the blue component was an InGaN blue-emitting chip.

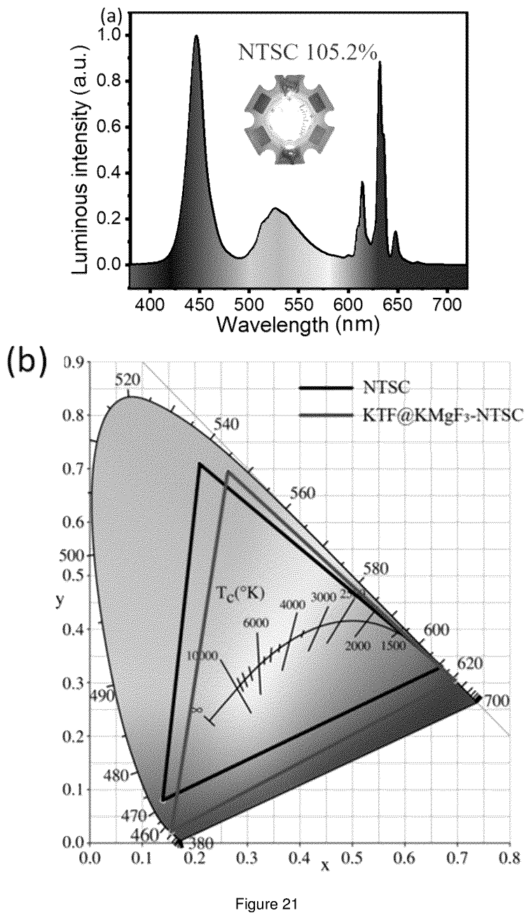

As shown in FIG. 21 (a), it was a spectra of a white light LED device packaged with K₂TiF₆:Mn⁴⁺@KMgF₃ in Example 1. As shown in FIG. 21 (b), it was a comparison diagram of a CIE color gamut diagram of the white light LED device in this example and a standard color gamut of the National Television System Committee. As shown in FIGS. 21 (a) and (b), the color gamut of the white light LED device in this example reaches 105.2% NTSC, and the luminous efficiency was 97.55 I m/W, so it was suitable as the display backlight source.

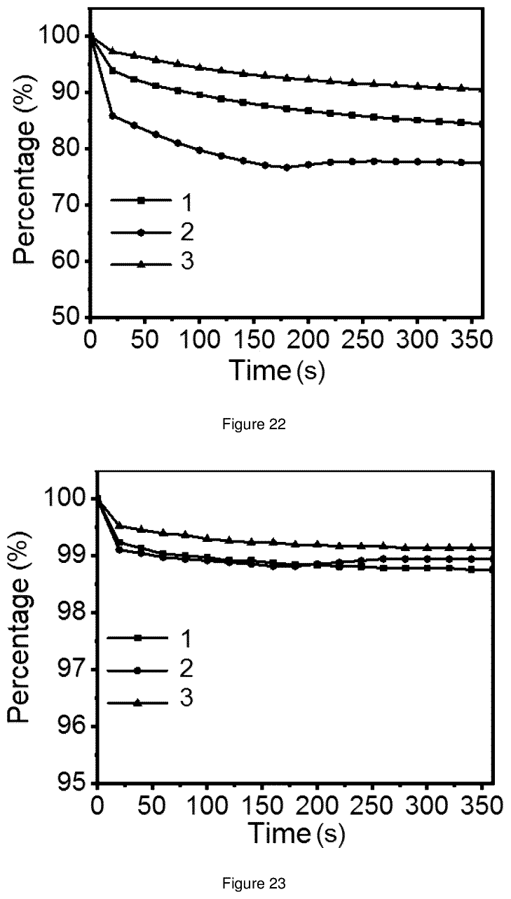

As shown in FIGS. 22 and 23, it was a thermal steady-state luminous flux attenuation curve and a thermal steady-state voltage attenuation curve of the white light LED device packaged with K₂TiF₆:Mn⁴⁺ (1), K₂TiF₆:Mn⁴⁺@KMgF₃ but not soaked in water (2), and K₂TiF₆:Mn⁴⁺@KMgF₃ after being soaked in water for 24 h (3), and it might be seen that: the stability of the device 3 was the best under double 85 test conditions (The temperature is 85 degrees Celsius and the humidity is 85 percent), after 360 seconds of testing, the luminous flux was attenuated to 90.55%, the device voltage was 99.13%, and compared to the device 1, the attenuation amplitude of the effect was significantly smaller.

As shown in Table 9, it was optoelectronic parameters of the devices 1, 2, and 3 under 120 mA current excitation.

TABLE 9

| | Luminous | Color | Luminous |
|---|---|---|---|
| Number | efficacy (Lm/W) | gamut (NTSC) | efficiency (%) |
| 1 | 93.05 | 105.2% | 47.6 |
| 2 | 89.46 | 105.2% | 38.9 |
| 3 | 97.55 | 105.2% | 46.8 |

### Comparative Examples 1-2

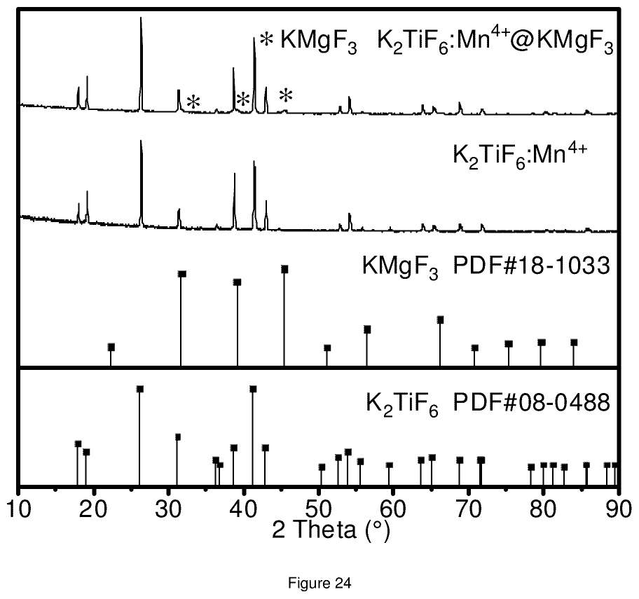

In Comparative examples 1-2, alkaline earth metal nitrate solution, Ca²⁺ and Sr²⁺, in the same family as Mg was respectively used to replace the Mg(NO₃)₂ aqueous solution and dropwise added into the mixed solution for coating treatment, and the other steps were the same as in Example 1. Results were shown in FIGS. 24-26:
the coated phosphor showed distinct characteristic peaks of the shell layer substance at the corresponding diffraction angles.

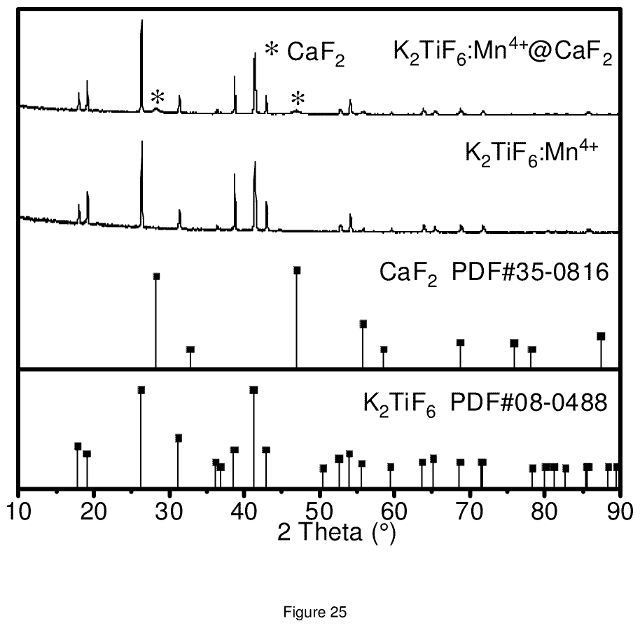

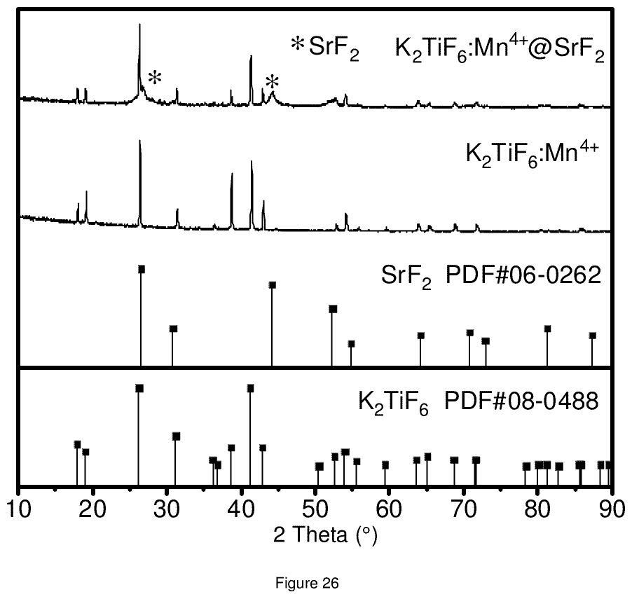

It might be seen from FIG. 24 that the XRD Patterns of K₂TiF₆:Mn⁴⁺ core-shell structure fluoride red phosphor of which the surface was coated by KMgF₃ in Example 1 showed the characteristic peak of KMgF₃ at diffraction angles of 31.63° and 45.42°;
it might be seen from FIG. 25 that the characteristic peak of CaF₂ appeared at diffraction angles of 28.27° and 47.00°; and
it might be seen from FIG. 26 that the characteristic peak of SrF₂ appeared at diffraction angles of 26.57° and 44.12°.

It was indicated that by using the same coating process and using different alkaline earth metal nitrates as the titration solution, only the addition of Mg²⁺ nitrate solution might generate KMgF₃.

Various embodiments of the present disclosure are already described above, and the above description is exemplary, not exhaustive, and is not limited to the embodiments disclosed. Many modifications and changes are apparent to those of ordinary skill in the art, without deviating from the scope and spirit of the embodiments described.

1. Wet-resistant fluoride red phosphor, wherein the fluoride red phosphor is a core-shell structure:
the core is Mn⁴⁺ doped fluoride red phosphor, and the chemical structural formula is A₂B₁₋ₓF₆:xMn⁴⁺, wherein A is at least one of Li, Na, K, Rb, and Cs, B is at least one of Ti, Si, Ge, Zr, and Sn, and 0≤x≤0.4; and
the shell is a cubic perovskite-type compound, and the chemical structural formula is CMgF₃, wherein C is at least one of Li, Na, K, Rb, and Cs.

2. The wet-resistant fluoride red phosphor according to claim 1, wherein the molar ratio of the shell to the core is 0.005-1.0.

3. The wet-resistant fluoride red phosphor according to claim 1, wherein A is at least one of Na and K, B is at least one of Ti and Si, and C is at least one of Na and K.

4. The wet-resistant fluoride red phosphor according to claim 1, wherein the molar ratio of the shell to the core is 0.2, 0.4, 0.6, 0.8, or 1.0.

5. The wet-resistant fluoride red phosphor according to claim 1, wherein the fluoride red phosphor is K₂TiF₆:0.08Mn⁴⁺@KMgF₃, the molar ratio of the shell to the core is 0.2.

6. The wet-resistant fluoride red phosphor according to claim 1, wherein the fluoride red phosphor is K₂SiF₆:0.08Mn⁴⁺@ KMgF₃, the molar ratio of the shell to the core is 0.2.

7. The wet-resistant fluoride red phosphor according to claim 1, wherein the fluoride red phosphor is K₂TiF₆:0.08Mn⁴⁺@NaMgF₃, the molar ratio of the shell to the core is 0.2.

8. A preparation method for the wet-resistant fluoride red phosphor according to claim 1, comprising the following steps:
S1: preparing CHF₂ aqueous solution and Mg(NO₃)₂ aqueous solution, wherein C is at least one of Li, Na, K, Rb, and Cs;
S2: mixing the Mn⁴⁺ doped fluoride red phosphor with the CHF₂ aqueous solution and stirring uniformly, to obtain mixed solution;
S3: continuously stirring the mixed solution, dropwise adding the Mg(NO₃)₂ aqueous solution into the mixed solution, and after dropwise adding, performing stirring, solid-liquid separating, washing, and drying sequentially, to obtain A₂B₁₋ₓF₆:xMn⁴⁺ core-shell structure fluoride red phosphor of which the surface is coated with CMgF₃; and
S4: soaking the A₂B₁₋ₓF₆:xMn⁴⁺ core-shell structure fluoride red phosphor of which the surface is coated with CMgF₃ in water, and performing the solid-liquid separating, washing, and drying, to obtain the wet-resistant fluoride red phosphor.

9. The preparation method for the wet-resistant fluoride red phosphor according to claim 8, wherein,
the molar concentration of the CHF₂ aqueous solution is 0.001-10 mol/L;
the molar concentration of the Mg(NO₃)₂ aqueous solution is 0.001-10 mol/L;
the usage amount ratio of the CHF₂ aqueous solution, the Mg(NO₃)₂ aqueous solution, and the Mn⁴⁺ doped fluoride red phosphor is (0.01-30) L: (0.01-10) L: 1 g; and
the molar amount of the Mn⁴⁺ doped fluoride red phosphor is 0.001-0.40 mol.

10. The preparation method for the wet-resistant fluoride red phosphor according to claim 8, wherein in Step S2, the stirring rate is 50-1200 rpm, and the stirring time is 0-60 min.

11. The preparation method for the wet-resistant fluoride red phosphor according to claim 8, wherein in Step S3,
the stirring rate of the continuously stirring is 50-1200 rpm;
the stirring rate after the dropwise adding is 50-1200 rpm, and the stirring time is 0-60 min; and
the dripping rate is 1-90 seconds/drop.

12. The preparation method for the wet-resistant fluoride red phosphor according to claim 8, wherein in Step S4, the soaking time is 1-60 h.

13. The preparation method for the wet-resistant fluoride red phosphor according to claim 8, wherein in Step S4, the soaking time is 12 h, 24 h, 48 h, or 60 h.

14. The preparation method for the wet-resistant fluoride red phosphor according to claim 8, wherein the preparation method comprising the following steps:
S1: preparing KHF₂ aqueous solution and the Mg(NO₃)₂ aqueous solution;
S2: mixing K₂TiF₆:xMn⁴⁺ with the KHF₂ aqueous solution and stirring for 30 min, to obtain mixed solution;
S3: continuously stirring the mixed solution, dropwise adding the Mg(NO₃)₂ aqueous solution into the mixed solution, and after dropwise adding, performing stirring for 30 min, performing solid-liquid separating, washing, and performing drying at 70° C., to obtain K₂TiF₆:xMn⁴⁺@KMgF₃; and
S4: soaking the K₂TiF₆:Mn⁴⁺@KMgF₃ in water for 24 h, and performing the solid-liquid separating, washing, and drying, to obtain the wet-resistant fluoride red phosphor.

15. An application of the wet-resistant fluoride red phosphor according to claim 1 used as a red component of a white light LED device serving as a display backlight source and a high color rendering and high contrast lighting source.

16. A white light LED device serving as a display backlight source and a high color rendering and high contrast lighting source, wherein the white light LED device comprises a red component, a green component, and a blue component; and
the red component is the wet-resistant fluoride red phosphor according to claim 1.

17. The white light LED device according to claim 16, wherein the green component is a green phosphor with a peak emission wavelength of 520-560 nm and a half peak width of less than 35 nm; and the blue component is an InGaN blue-emitting chip.
